(19) United States
(12) Patent Application Publication
(10) Pub. No.: US 2007/0052001 A1
(43) Pub. Date: Mar. 8, 2007

(54) Nonvolatile semiconductor memory device and method of fabricating the same

(75) Inventors: Seung-eon Ahn, Suwon-si (KR); Jung-bin Yun, Yongin-si (KR); In-kyeong Yoo, Suwon-si (KR); Dong-chul Kim, Suwon-si (KR); Tae-hoon Kim, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/502,426

(22) Filed: Aug. 11, 2006

(30) Foreign Application Priority Data
Aug. 12, 2005 (KR) 10-2005-0074495

(51) Int. Cl. H01L 29/76

(52) U.S. Cl. 257/314

(57) ABSTRACT

A nonvolatile semiconductor memory device and a method of fabricating the same are provided. The nonvolatile memory device may include a switching device and a storage node connected to the switching device. The storage node may comprise a lower electrode, a data storing layer, and an upper electrode. The data storing layer may include a first region where a current path is formed at a first voltage, and a second region surrounding the first region where a current path is formed at a second voltage, greater than the first voltage. The first region may be positioned to contact the upper electrode and the lower electrode.

### PRIORITY STATEMENT

This application claims the benefit of Korean Patent Application No. 10-2005-0074495, filed on Aug. 12, 2005, in the Korean Intellectual Property Office, the disclosure of which is incorporated herein in its entirety by reference.

### BACKGROUND

1. Field

Example embodiments relate to a semiconductor memory device and a method of fabricating the same, for example, to a nonvolatile semiconductor memory device including a phase transition layer and a method of fabricating the same.

2. Description of the Related Art

In recent years, next generation nonvolatile memory devices having features of volatile memory devices and nonvolatile memory devices, for example, ferroelectric random access memories (FRAMs), phase change random access memories (PRAM), magnetoresistive random access memories (MRAMs) and resistance random access memories (RRAMs), have been studied.

FRAMs, PRAMs, MRAMs and RRAMs have a relatively high-speed write operation. However, FRAMs may be difficult to develop as a mass memory because cells of an FRAM may be difficult to scale down. PRAMs are easier to scale down and may require a lower reset current for lower power consumption. MRAM may be difficult to manufacture with mass capacity because they require a higher write current and have a smaller sensing margin for data signal discrimination.

Conventional RRAMs may be priced comparable to a flash memory or a dynamic random access memory (DRAM) because RRAMs may be scaled down relatively easily. Conventional RRAMs also have a relatively short access time, perform a non-destructive reading operation and may be relatively easy to develop as a mass memory.

However, conventional RRAM may suffer from set and/or reset voltage scattering and high set voltage. Conventional RRAM may also suffer from reset current scattering and high reset current.

When the reset current is too great for a transistor included in the RRAM to accommodate, a size of the transistor is difficult to reduce. The size of the transistors may limit integration of an RRAM.

### SUMMARY

Example embodiments provide a nonvolatile semiconductor memory device having a reduced set voltage, reduced scattering of a set voltage, a reset voltage and/or reset current, and/or a reduced reset current.

Example embodiments provide a method of fabricating a nonvolatile semiconductor memory device.

According to an example embodiment, there is provided a nonvolatile memory device including a storage node, the storage node comprising a lower electrode, a data storing layer, including a first region where a current path is formed at a first voltage, and a second region surrounding the first region where a current path is formed at a second voltage greater than the first voltage, and an upper electrode, wherein the first region is located between the upper electrode and the lower electrode to contact the upper electrode and the lower electrode.

In an example embodiment, the first region is of a nanometer size.

In an example embodiment, the data storing layer is a transition metal oxide layer.

In an example embodiment, the lower electrode is made of platinum.

In an example embodiment, the upper electrode is made of platinum.

In an example embodiment, the lower electrode and the upper electrode are made of the same material.

In an example embodiment, the data storing layer is a phase transition layer has a different resistance in a first state and a second state, depending on an applied voltage.

According to an example embodiment, the device further includes a switching device connected to the storage node.

According to an example embodiment, there is provided a method of fabricating a storage node of a nonvolatile memory device, the method including forming a data storing layer on a lower electrode, applying a stress to a local region of the data storing layer, and forming an upper electrode on a first region of the data storing layer including the local region.

In an example embodiment, the method further includes forming a photoresitive layer pattern on the data storing layer to expose the first region prior to applying the stress.

In an example embodiment, forming the upper electrode includes forming an upper electrode layer on the first region and the second region and removing the photoresitive layer pattern and the upper electrode layer on the second region.

In an example embodiment, forming the upper electrode includes forming the upper electrode layer on the first region.

In an example embodiment, the stress is a voltage stress.

In an example embodiment, applying the voltage stress includes aligning a voltage supply unit on the local region of the data storing layer, contacting the voltage supply unit with the local region of the data storing layer, and applying a voltage to the local region of the data storing layer via the voltage supply unit.

In an example embodiment, the voltage supply unit is a C-AFM (conducting-atomic force microscopy) probe.

In an example embodiment, the local region is of a nanometer size.

In an example embodiment, the data storing layer is formed of a transition metal oxide layer.

In an example embodiment, the stress is a voltage stress or a current stress.

In an example embodiment, the method further includes forming a switching device connected to the storage node.

### BRIEF DESCRIPTION OF THE DRAWINGS

Example embodiments will be described in more detail with reference to the attached drawings in which:

FIG. 1 is a cross-sectional view illustrating a nonvolatile memory device according to an example embodiment;

FIGS. 2 through 8 are cross-section views illustrating a method of fabricating a nonvolatile semiconductor memory device (RRAM) shown in FIG. 1 according to an example embodiment of the present invention;

FIGS. 9 and 10 are cross-sectional views illustrating a method of fabricating the nonvolatile semiconductor memory device shown in FIG. 1 according to another example embodiment;

FIG. 11 is an example photograph illustrating topography of a portion of a data storing layer formed of NiO;

FIG. 12 is an example photograph illustrating a current image of a data storing layer that is measured at a given voltage after a voltage stress is applied to the first region A1 using a conducting-atomic force microscopy (C-AFM) probe in FIG. 11;

FIG. 13 is an example graph illustrating a current-voltage property in a forming process or setting process for a first region A1 to which a voltage stress is applied in FIG. 11; and

FIG. 14 is an example graph illustrating a current-voltage property in a forming process or setting process for a second region A2 to which a voltage stress is not applied in FIG. 11.

### DETAILED DESCRIPTION OF EXAMPLE EMBODIMENTS

Examples will now be described more fully with reference to the accompanying drawings. In the drawings, the thicknesses of layers and regions are exaggerated for clarity.

Example embodiments are described more fully hereinafter with reference to the accompanying drawings. Example embodiments are provided so that this disclosure will be thorough and complete, and will fully convey the scope of the appended claims to those skilled in the art.

It will be understood that when an element or layer is referred to as being “on,” “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element or component, from another element or component. Thus, a first element or component discussed below could be termed a second element or component without departing from the teachings of example embodiments.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It should also be noted that in some alternate implementations, the functions/acts noted in the blocks may occur in an order other than those set forth in the flowcharts. For example, two blocks shown in succession may in fact be executed substantially concurrently or the blocks may sometimes be executed in the reverse order, depending upon the functionality/acts involved.

Hereinafter, a nonvolatile semiconductor memory device and a method of fabricating the same according to example embodiments will be described in detail with reference to the accompanying drawings. The thickness of shown layers or regions is exaggerated for illustration. Further, a substrate and a transistor are not shown in FIGS. 5 through 14 for convenience of illustration.

A nonvolatile semiconductor memory device according to an example embodiment will be described.

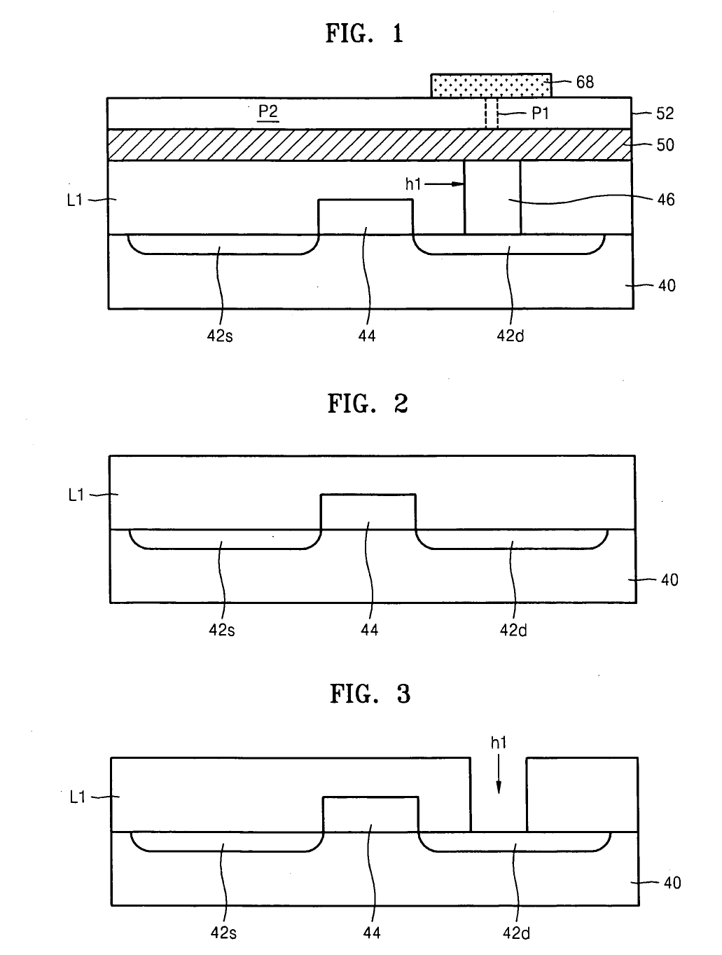

Referring to FIG. 1, first and second impurity regions 42s and 42d may be formed in a substrate 40. The first and second impurity regions 42s and 42d may be doped with an impurity having conductivity that is different from that of an impurity doped in the substrate 40. One of the first and second impurity regions 42s and 42d may be used as a source region and the other may be used as a drain region. A gate stack 44 may be provided on the substrate 40, for example, between the first and second impurity regions 42s and 42d. The gate stack 44 may include a gate insulating layer and/or a gate electrode. The first and second impurity regions 42s and 42d and the gate stack 44 may constitute a switching device, for example, a field effect transistor.

An interlayer insulating layer, for example, a flat interlayer insulating layer L1 may be formed on the substrate 40 to cover all or part of the switching device. A contact hole h1 may be formed in the interlayer insulating layer L1 to expose the second impurity region 42d. The contact hole h1 may be filled with a conductive plug 46. The conductive plug 46 may be aluminum or doped polysilicon.

A lower electrode 50 may be formed on the interlayer insulating layer L1 to cover the conductive plug 46. The lower electrode 50 may be a platinum (Pt) electrode. A data storing layer 52 and an upper electrode 68 may be sequentially stacked on the lower electrode 50. The lower electrode 50, the data storing layer 52 and the upper electrode 68 may constitute a storage node. The upper electrode 68 may be formed of the same material as the lower electrode 50.

The data storing layer 52 may be a phase transition layer having different resistance in a first state and a second state, depending on an applied voltage. The data storing layer 52 may include a first region P1 and a second region P2. The second region P2 may surround the first region P1. The second region P2 may be defined as a region of the data storing layer 52 excluding the first region P1. The first region P1 may be located between the upper and lower electrodes 68 and 50. The area of the top surface of the first region P1 may be on the order of nanometers.

The first region P1 may be a region to which a voltage stress is applied. As a result, the first region P1 may have a weakened bonding force between constituent materials, compared to the second region P2. Accordingly, a voltage needed to form a current path in the first region P1 may be lower than a voltage needed to form a current path in the second region P2. In operation of the nonvolatile memory device, e.g., an RRAM according to an example embodiment, therefore, current paths may be formed only or substantially only in the first region P1 of the data storing layer 52, not in the second region P2.

A method of fabricating a nonvolatile semiconductor memory device according to an example embodiment will be described.

Referring to FIG. 2, first and second impurity regions 42s and 42d and a gate stack 44 including a gate electrode may be formed on a substrate 40, forming a switching device, for example, a transistor. The substrate 40 may be a p or n type semiconductor substrate. The first and second impurity regions 42s and 42d may be formed in the substrate 40, in which the impurity regions are doped with an impurity having conductivity that has a different polarity from that of the substrate 40. An interlayer insulating layer, for example a flat interlayer insulating layer L1 may be formed on the substrate 40 to cover the transistor. A contact hole h1 may be formed in the interlayer insulating layer L1 to expose the second impurity region 42d, as shown in FIG. 3.

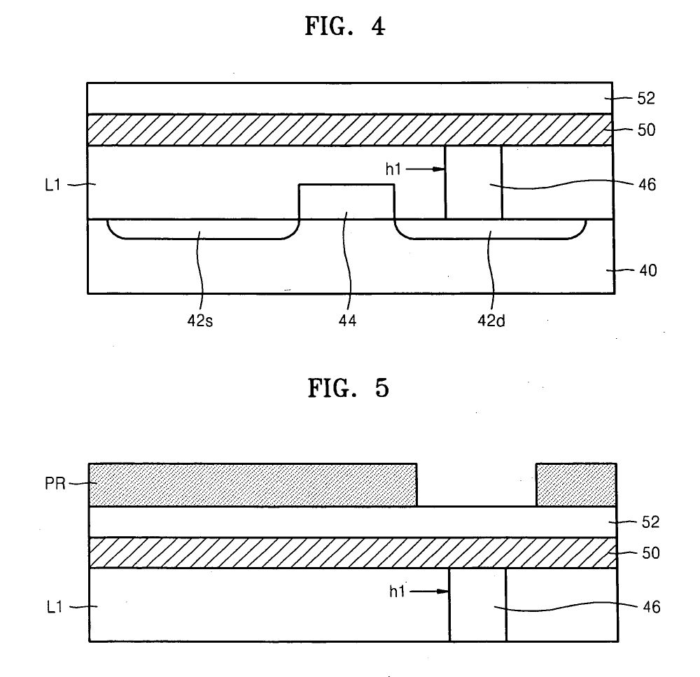

The contact hole h1 may be filled with a conductive plug 46, as shown in FIG. 4. The conductive plug 46 may be formed of aluminum, doped polysilicon, or the like. After the contact hole h1 is filled, a lower electrode 50 and/or a data storing layer 52 may be sequentially formed on the interlayer insulating layer L1. The lower electrode 50 may be formed to cover an exposed surface of the conductive plug 46. The lower electrode 50 may be formed of, for example, a platinum (Pt) electrode.

The data storing layer 52 may be nonvolatile. The data storing layer 52 may have different resistance in a first state and a second state, depending on an applied voltage. The first and second states of the data storing layer 52 need not change until a phase transition voltage is applied to the data storing layer 52. The data storing layer 52 may be formed of a transition metal oxide layer. The transition metal oxide layer may be formed of, for example, a nickel oxide (NiO) layer or a hafnium oxide (HfO₂) layer.

Referring to FIG. 5, a photoresitive layer pattern PR may be formed on the data storing layer 52 to expose a portion of the data storing layer 52. The photoresitive layer pattern PR may define a region where an upper electrode is to be formed on an upper or top surface of the data storing layer 52. In a post-process, for example, the upper electrode may be formed in the exposed portion of the data storing layer 52.

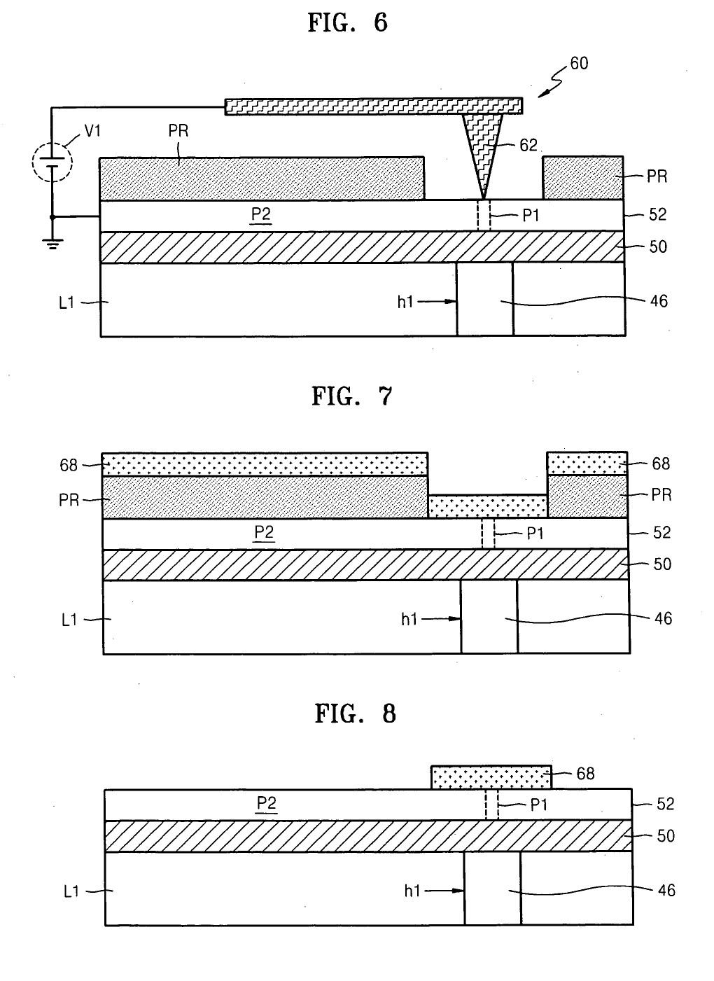

Referring to FIG. 6, a conducting-atomic force microscopy (C-AFM) probe 60 is aligned on the exposed region of the data storing layer 52 and then laid down so that a tip 62 of the probe 60 contacts the first region P1 within the exposed region of the data storing layer 52. A predetermined or given voltage V1 may be applied between the probe 60 and the data storing layer 52. The voltage V1 may create a voltage stress so that a bonding force of the first region P1 of the data storing layer 52 contacting with the tip 62 is lowered or a current path is created. For example, the voltage V1 may be on the order of 8 to 10 V.

This voltage stress may weaken a bonding force between constituent materials of the first region P1 of the data storing layer 52, positioned between the tip 62 and the lower electrode 50. Accordingly, a current path, which may be formed in an initial current path forming process, that is, a forming process performed after the nonvolatile memory device is completed, or in a set process of the memory device following the forming process, may be first formed in the first region P1 of the data storing layer 52 to which the voltage stress is applied. Because a bonding force between the constituent material in the first region P1 is weakened compared to that in the second region P2 of the data storing layer 52 to which the voltage stress is not applied, as described above, one or more current paths in the first region P1 may be formed at a voltage lower than a minimum voltage needed to form one or more current paths in the second region P2. The one or more current paths formed in the first region P1 may be directed to the lower electrode 50. In another example embodiment, instead of or in addition to the voltage stress, one or more other another stresses, for example, a current stress may be applied to the first region P1.

Because the tip 62 contacting the data storing layer 52 has an area of nanometer size, the upper or top surface of the first region P1 of the data storing layer 52 also has an area of nanometer size. As such, the tip 62 and the data storing layer 52 contact each other at a relatively small contact area, and thus, a few or less current paths, e.g., one current path may be formed in the first region P1 of the data storing layer 52 in the forming or setting process.

As a reset voltage is applied to the data storing layer 52 to be in the off state, the current path formed in the first region P1 in the forming process or the setting process may disappear but a trace thereof may remain. That is, the current path formed in the first region P1 may be retained or stored in the data storing layer 52. Accordingly, when the reset voltage is applied to the data storing layer 52 and then the set voltage is applied, a current path is again formed along the trace of the current path already formed in the first region P1. Because only one or a few current paths are formed, a set voltage needed to form the current path in the first region P1 again becomes lower than the previous set voltage.

Once the current path is again formed in the first region P1 of the data storing layer 52, the data storing layer 52 is in an ON state. Accordingly, there is no need to form a current path in the second region P2 of the data storing layer 52. This means that ON/OFF switching operation of the data storing layer 52 may be controlled by controlling only the current path formed in the first region P1. In view of the fact that only one or a few current paths are formed in the first region P1 of the data storing layer 52 in the forming process or the setting process, it can be seen that a voltage needed to switch the data storing layer 52 from an ON state to an OFF state or vice versa, that is, a reset voltage and set voltage are relatively more constant, that scattering of the reset voltage and the set voltage may be ignored.

Because the number of the current paths used in the switching is less than that of conventional art, the reset current of example embodiments, may be smaller than a conventional reset current.

Referring to FIG. 7, after the voltage stress is applied to the first region of the data storing layer 52 as described above, an upper electrode 68 may be formed on the exposed region of the data storing layer 52. The upper electrode 68 may also be formed on the photosensitive layer pattern PR. The photoresitive layer pattern PR may be removed by a lift off method. The portion of the upper electrode 68 formed on the photoresitive layer pattern PR may be removed at the same time. As a result, the upper electrode 68 may be formed on the exposed region, that is, the first region P1 of the data storing layer 52, as shown in FIG. 8. This results in the storage node including the lower electrode 50, the data storing layer 52, and the upper electrode 68 formed on the interlayer insulating layer L1.

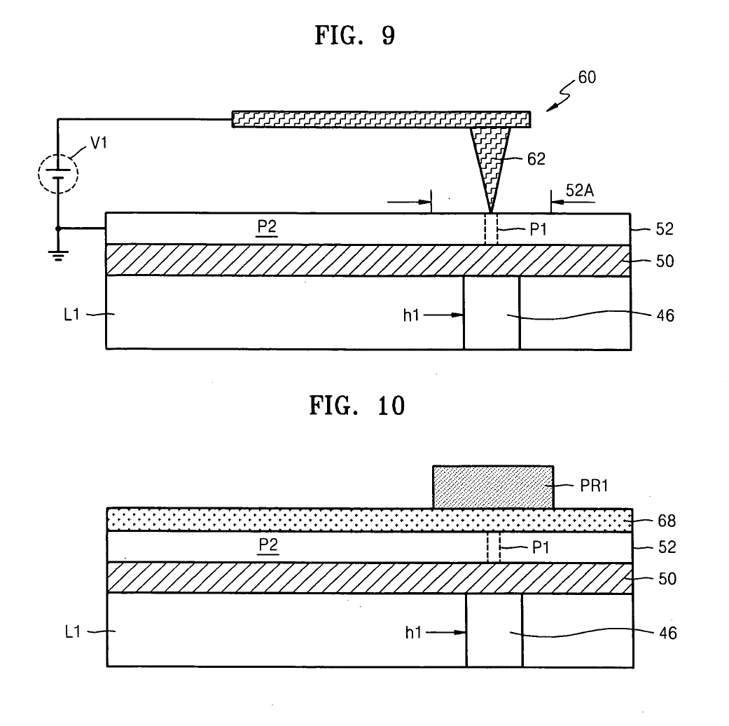

Only differences between the example embodiments of FIGS. 2 through 8 and the example embodiments of FIGS. 9 and 10 will be described. The same elements as those of the example embodiments of FIGS. 2 through 8 are given the reference numbers as used in the example embodiments of FIGS. 2 through 8.

Referring to FIG. 9, a data storing layer 52 may be formed on the lower electrode 50, and a voltage or other stress may be applied to the first region P1 in the local region 52A of the data storing layer 52 where an upper electrode may be formed in a post-process, using, for example, a C-AFM probe 60. The voltage stress may be applied in the same way as illustrated in FIG. 6. The voltage stress may weaken a bonding force between constituent materials of the first region P1.

A current path formed in the first region P1 of the local region 52A in a forming process or a setting process of a nonvolatile memory device may be formed over the conductive plug 46. Therefore, the first region P1 of the data storing layer 52 contacting the C-AFM probe 60 may be positioned directly over the conductive plug 46.

Referring to FIG. 10, an upper electrode 68 may be formed on the data storing layer 52 to which the voltage stress is applied. A photoresitive layer pattern PR1 may be formed on the upper electrode 68 to define a portion of the upper electrode 68. The photosensitive layer pattern PR1 may be formed to be positioned over the conductive plug 46. The upper electrode 68 around the photosensitive layer pattern PR1 may be etched using the photoresitive layer pattern PR1 as an etching mask. The etching may be a dry etching. After the upper electrode 68 is etched, the photoresitive layer pattern PR1 may be ashed, stripped and removed. The result is shown in FIG. 8.

After the upper electrode 68 around the photoresitive layer pattern PR1 is etched, the data storing layer 52 and the lower electrode 50 around the photosensitive layer pattern PR1 may be etched with sequentially changed etching conditions corresponding to the data storing layer 52 and the lower electrode 50.

Experiments conducted in connection with the memory device of example embodiments will be now described.

In the example embodiments of FIGS. 2 through 8 and example embodiments of FIGS. 9 and 10, the data storing layer 52 was formed of NiO and a first region of the data storing layer 52 to which the voltage stress is to be applied was selected. A second region to be compared to the first region was also selected in a region surrounding the first region to which the voltage stress is not applied. The first and second regions may have a different area. However, the areas of the first and second regions are similar to an area of the tip 62 of the C-AFM probe 60 contacting the data storing layer 52.

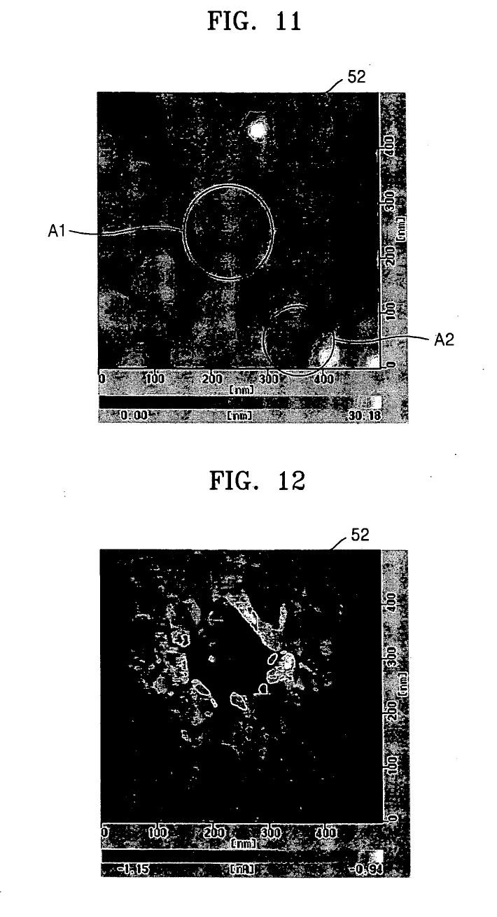

FIG. 11 is an example photograph illustrating topography of a portion of a data storing layer formed of NiO. In FIG. 11, reference numerals A1 and A2 denote the first region and the second region, respectively.

Referring to FIG. 11, the first region A1 undergoes a change in a surface state due to the applied voltage stress. This is because the bonding force of the data storing layer 52 is weakened.

FIG. 12 illustrates an example current image of a data storing layer 52 that is measured at a given voltage after a voltage stress is applied to the first region A1 in FIG. 11 using a conducting-atomic force microscopy (C-AFM) probe, that is, a scattering of a region of the data storing layer 52 where current flows and a region wherein current does not flow. In this measurement, the given voltage is lower than a minimum voltage that forms a current path in the second region of the data storing layer 52 to which a voltage stress is not applied.

Referring to FIG. 12, in the data storing layer 52, only a specific region is bright and other regions are dark. The bright region corresponds to the first region A1 of FIG. 11 and is a region where current flows, that is, where the current path is formed.

FIG. 12 illustrates that in the data storing layer 52, the current path is formed in the first region A1 to which the voltage stress is applied, at a voltage lower than a minimum forming or set voltage needed to form a current path in the second region A2 to which the voltage stress is not applied.

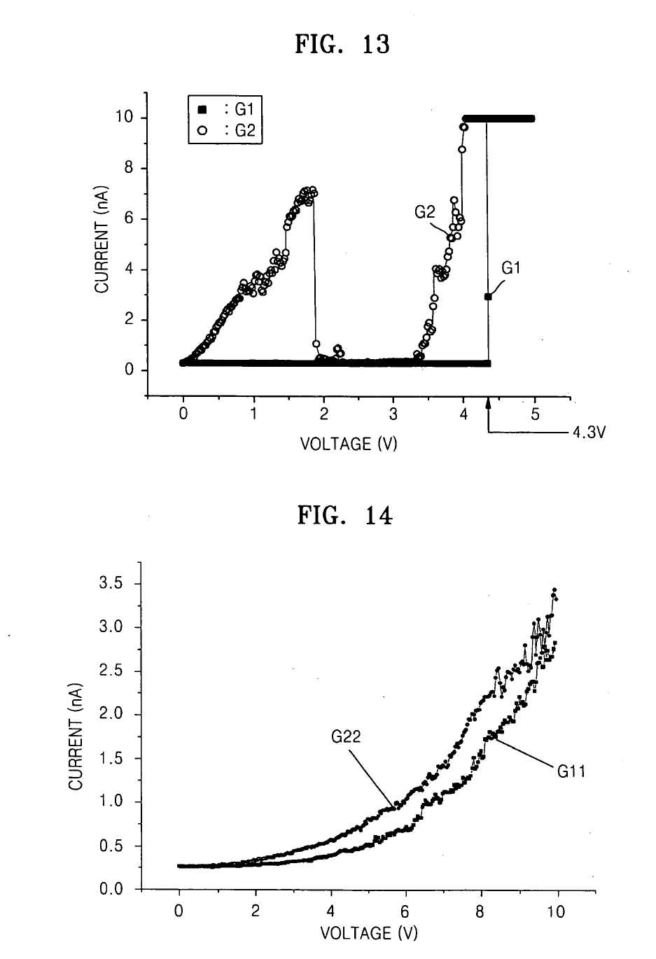

FIG. 13 illustrates a current-voltage property of the first region A1 of the data storing layer 52 that is formed of NiO in FIG. 11, and FIG. 14 illustrates a current-voltage property of the second region A2.

In FIG. 13, the first graph G1 shows a current-voltage property in the process of forming the first region A1 of the data storing layer 52, and the second graph G2 shows a current-voltage property in the setting process performed on the first region A1 of the data storing layer 52 that becomes at an off state in the resetting process.

Referring to the first and second graphs G1 and G2 of FIG. 13, the first region A1 of the data storing layer 52 is formed at 4.3 V and then becomes at a set state at 4V or less.

In FIG. 14, the first graph G11 shows a current-voltage property in the process of forming the second region A2 of the data storing layer 52, and the second graph G22 shows a current-voltage property in the setting process performed on the second region A2 of the data storing layer 52 that becomes at an off state in the resetting process conducted subsequent to the forming process.

Referring to the first and second graphs G11 and G22 of FIG. 14, the second region A2 of the data storing layer 52 to which the voltage stress is not applied is neither formed of a current path nor becomes at the set state until the voltage reaches 10 V.

From the results shown in FIGS. 13 and 14, it can be seen that the switching property in the data storing layer 52 appears only in the first region A1 to which the voltage stress is applied, and the forming or set voltage for the first region A1 is lower than that for the second region A2 to which the voltage stress is not applied.

While example embodiments have been provided, they are illustrative and not limiting. For example, the voltage stress may be applied to the first region P1 of the data storing layer 52 by those skilled in the art using a device other than a C-AFM. Thus, the scope of example embodiments is not defined by the disclosure embodiments but is defined by the following claims.

As described above, according to example embodiments, it is possible to limit a region in the data storing layer where a current path is formed, to a local region in the forming process or the setting process by applying a voltage stress to the local region of the data storing layer using, for example, a C-AFM probe. Because an area of the tip of the C-AFM probe contacting the local region of the data storing layer is as small as the order of nanometers, only one or a few current paths may be formed in the local region. As a result, the forming process or the setting process may be controlled by controlling only one or a few current paths, thereby lowering the forming and/or set voltages, obtaining negligibly small scattering of a set voltage, a reset voltage and/or reset current, and/or reducing the reset current.

While example embodiments have been shown and described, it will be understood by those of ordinary skill in the art that various changes in form and details may be made therein without departing from the spirit and scope of example embodiments as defined by the following claims.

What is claimed is:

1. A nonvolatile memory device including a storage node, the storage node comprising:
a lower electrode;
a data storing layer, including a first region where a current path is formed at a first voltage, and a second region surrounding the first region where a current path is formed at a second voltage greater than the first voltage; and
an upper electrode;
wherein the first region is located between the upper electrode and the lower electrode to contact the upper electrode and the lower electrode.

2. The device of claim 1, wherein the first region is of a nanometer size.

3. The device of claim 1, wherein the data storing layer is a transition metal oxide layer.

4. The device of claim 1, wherein the lower electrode is made of platinum.

5. The device of claim 1, wherein the upper electrode is made of platinum.

6. The device of claim 1, wherein the lower electrode and the upper electrode are made of the same material.

7. The device of claim 1, wherein the data storing layer is a phase transition layer having a different resistance in a first state and a second state, depending on an applied voltage.

8. The device of claim 1, further comprising:
a switching device connected to the storage node.

9. A method of fabricating a storage node of a nonvolatile memory device, the method comprising:
forming a data storing layer on a lower electrode;
applying a stress to a local region of the data storing layer; and
forming an upper electrode on a first region of the data storing layer including the local region.

10. The method of claim 9, further comprising:
forming a photoresitive layer pattern on the data storing layer to expose the first region prior to applying the stress.

11. The method of claim 10, wherein forming the upper electrode includes:
forming an upper electrode layer on the first region and the photoresitive layer pattern; and
removing the photoresitive layer pattern and the upper electrode layer on the photoresitive layer pattern.

12. The method of claim 10, wherein forming the upper electrode includes:
forming an upper electrode layer on the first region.

13. The method of claim 9, wherein the stress is a voltage stress.

14. The method of claim 13, wherein applying the voltage stress includes:
aligning a voltage supply unit on the local region of the data storing layer;
contacting the voltage supply unit with the local region of the data storing layer; and
applying a voltage to the local region of the data storing layer via the voltage supply unit.

15. The method of claim 14, wherein the voltage supply unit is a C-AFM (conducting-atomic force microscopy) probe.

16. The method of claim 9, wherein the local region is of a nanometer size.

17. The method of claim 9, wherein the data storing layer is formed of a transition metal oxide layer.

18. The method of claim 9, wherein the stress is a current stress.

19. The method of claim 9, further comprising:
forming a switching device connected to the storage node.
